(19) United States
(12) Patent Application Publication
(10) Pub. No.: US 2026/0106418 A1
(43) Pub. Date: Apr. 16, 2026

(54) POWER INDICATOR FOR USE WITH ELECTRICAL CABLES

(71) Applicant: DCD Enterprises, LLC, St. George, UT (US)

(72) Inventors: Bryce Dalton, Circleville, UT (US); Tyler Moore, Elsinore, UT (US); Lon Dalton, St. George, UT (US); Justin Pratt, San Clemente, CA (US)

(73) Assignee: DCD Enterprises, LLC, St. George, UT (US)

(21) Appl. No.: 19/356,853

(22) Filed: Oct. 13, 2025

Related U.S. Application Data
(60) Provisional application No. 63/706,159, filed on Oct. 11, 2024.

(51) Int. Cl. H01R 13/66; F02N 19/04; G01R 19/165; H01R 13/46; H01R 13/717; H01R 31/06

(52) U.S. Cl. CPC H01R 13/6683; G01R 19/16533; H01R 13/465; H01R 13/7175; H01R 31/065; F02N 19/04; H01R 2201/26

(57) ABSTRACT

A power indicator for extension cords has a male connector at a first end and a female receptacle at a second end, a transformer interposed between, and electrically coupled to, the male connector and female receptacle, the transformer configured to read a load on a circuit and illuminate at least one LED when the load is above a predetermined threshold, indicating that a block heater or other device is drawing power. When connected to an engine block heater, a user can confirm that the block heater is drawing power by the indication of the LED.

### CROSS-REFERENCE TO RELATED APPLICATIONS

This application claims the benefit of U.S. Provisional Application Ser. No. 63/706,159 filed on Oct. 11, 2024, which is incorporated herein by reference.

### TECHNICAL FIELD

The present disclosure relates to a device for indicating when a voltage load is present and drawing current in connection with an electrical cable.

### BACKGROUND

Internal combustion engines (ICE) start and run better when warm. This is particularly true for diesel engines, which often require glow plugs to reach a predetermined temperature before starting to ensure proper combustion. Additionally, it is recommended to not run an ICE under full load until the engine is warm, to ensure that the ICE is not overstressed and subject to premature failure. However, there are many instances when the ICE will be started when cold (such as not having been started for a day), or will be subjected to lower ambient temperatures. Indeed, both gas and diesel combustion engines may struggle to start when the ambient temperatures are cold or freezing. Even if started in cold or freezing conditions, an operator may need to wait significantly longer for the ICE to reach ideal operating temperature before applying a full load.

When the ICE fails to start, it can lead to adverse consequences, including additional wear on the starter and other engine components, draining the starter battery due to repeated attempts to start at cold temperatures, and flooding the engine, among others. Additionally, the driver or operator may be unable to complete their desired tasks on the desired timeline, which, in commercial cases, can lead to liability (e.g., failed delivery of goods according to a contract).

In an effort to solve this problem, engine block heaters have been implemented. These block heaters are configured to heat up selected components of the ICE or vehicle, and are often situated to heat internal fluids such as motor oil or engine coolant, making them less viscous and the engine easier to start. Some block heaters are incorporated into the ICE, while others may be coupled externally. Regardless of the type of block heater, they all have one thing in common: the need for external power. An extension cord is typically run from a house or other building to provide grid power to the block heater. However, there are many instances when the extension cord is faulty, has become unplugged on one of the ends without the user realizing, or the block heater is no longer functioning. In each case, the user may not realize that the block heater is not operating. As a result, the ICE is not warmed and ready when the user expects it to be, with no warning to the user in advance.

Accordingly, there is a need for an apparatus configured to indicate when there is a voltage load and current draw on the cable, indicating that power is flowing through the extension cord and that the block heater (or other device) is drawing that power. The present disclosure seeks to solve these and other problems.

### SUMMARY OF EXAMPLE EMBODIMENTS

In some embodiments, a power indicator comprises an extension cord comprising a male connector at a first end and a female receptacle at a second end, and a current transformer interposed between the first end and the second end, the transformer configured to read a load on the circuit, and an LED configured to illuminate when the load is above a predetermined threshold, indicating that the block heater is drawing power. In some embodiments, the LED is implemented with a jumper having a 120V, 15 amp receptacle.

In some embodiments, a power indicator comprises a pigtail connector having either a male connector or female connector at a first end and bare wires at a second end, the pigtail connector further comprising a transformer interposed between the first end and second end, the transformer configured to read a load on a circuit and to illuminate an LED when the load is above a predetermined threshold, indicating that the block heater is drawing power. In some embodiments, the LED is implemented with a jumper having a 120V, 15 amp receptacle.

In some embodiments, a power indicator comprises an extension cord comprising a male connector at a first end and a female receptacle at a second end, wherein the male connector further comprises a current transformer configured to read a load on the circuit, and an LED configured to illuminate when the load is above a predetermined threshold, indicating that the block heater is drawing power.

In one method of use, a user couples the male connector of an extension cord to a power source (e.g., grid power), and couples the female receptacle to the male connector of the block heater. If the extension cord is connected to power and the block heater is drawing power, placing a load on the circuit, an LED illuminates to indicate to a user that the block heater is functioning.

### BRIEF DESCRIPTION OF THE DRAWINGS

FIG. 1 illustrates a top plan view of a power indicator;

FIG. 2 illustrates a side perspective view of a power indicator;

FIG. 3 illustrates a side perspective view of a power indicator with a housing removed;

FIG. 4 illustrates a side elevation view of a power indicator with a transparent housing; and

FIG. 5 illustrates a side perspective view of a power indicator in a pigtail configuration.

### DETAILED DESCRIPTION OF EXAMPLE EMBODIMENTS

The following descriptions depict only example embodiments and are not to be considered limiting in scope. Any reference herein to “the invention” is not intended to restrict or limit the invention to exact features or steps of any one or more of the exemplary embodiments disclosed in the present specification. References to “one embodiment,” “an embodiment,” “various embodiments,” and the like, may indicate that the embodiment(s) so described may include a particular feature, structure, or characteristic, but not every embodiment necessarily includes the particular feature, structure, or characteristic. Further, repeated use of the phrase “in one embodiment,” or “in an embodiment,” do not necessarily refer to the same embodiment, although they may.

Reference to the drawings is done throughout the disclosure using various numbers. The numbers used are for the convenience of the drafter only and the absence of numbers in an apparent sequence should not be considered limiting and does not imply that additional parts of that particular embodiment exist. Numbering patterns from one embodiment to the other need not imply that each embodiment has similar parts, although it may.

Accordingly, the particular arrangements disclosed are meant to be illustrative only and not limiting as to the scope of the invention, which is to be given the full breadth of the appended claims and any and all equivalents thereof. Although specific terms are employed herein, they are used in a generic and descriptive sense only and not for purposes of limitation. Unless otherwise expressly defined herein, such terms are intended to be given their broad, ordinary, and customary meaning not inconsistent with that applicable in the relevant industry and without restriction to any specific embodiment hereinafter described. As used herein, the article “a” is intended to include one or more items. When used herein to join a list of items, the term “or” denotes at least one of the items, but does not exclude a plurality of items of the list. For exemplary methods or processes, the sequence and/or arrangement of steps described herein are illustrative and not restrictive.

It should be understood that the steps of any such processes or methods are not limited to being carried out in any particular sequence, arrangement, or with any particular graphics or interface. Indeed, the steps of the disclosed processes or methods generally may be carried out in various sequences and arrangements while still falling within the scope of the present invention.

The term “coupled” may mean that two or more elements are in direct physical contact. However, “coupled” may also mean that two or more elements are not in direct contact with each other, but yet still cooperate or interact with each other.

The terms “comprising,” “including,” “having,” and the like, as used with respect to embodiments, are synonymous, and are generally intended as “open” terms (e.g., the term “including” should be interpreted as “including, but not limited to,” the term “having” should be interpreted as “having at least,” the term “includes” should be interpreted as “includes, but is not limited to,” etc.).

As previously discussed, there is a need for an apparatus configured to indicate when there are a voltage load and current draw on the cable, indicating that power is flowing through the extension cord and that the block heater is drawing that power. The power indicator disclosed herein solves these problems and others.

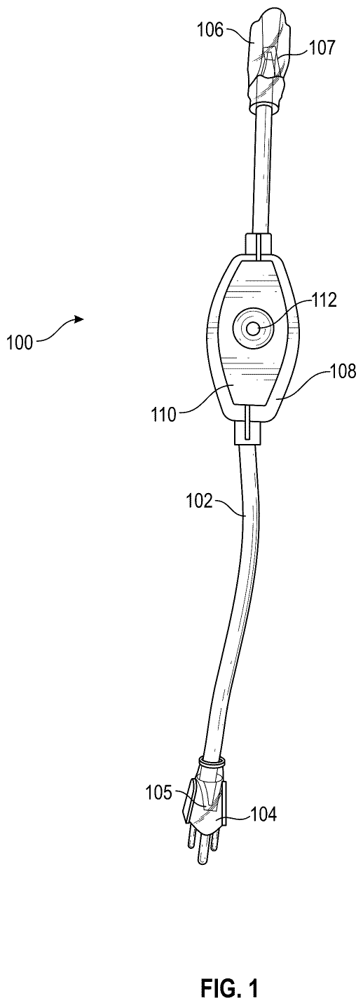

Referring now to FIG. 1, in some embodiments, a power indicator 100 comprises an extension cord 102, a male connector 104 at a first end, and a female receptacle 106 at a second end. The power indicator 100 further comprises a housing 108 comprising a transformer 110 configured to read a load on a circuit and illuminate an LED 112 when the load is above a predetermined threshold, indicating that the block heater is drawing power. In some embodiments, the LED 112 is implemented with a jumper having a 120V 15 amp receptacle, although other configurations may be used without departing herefrom.

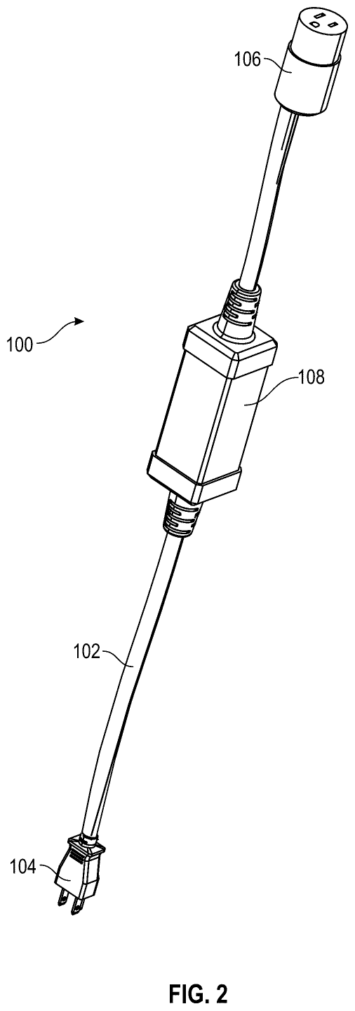

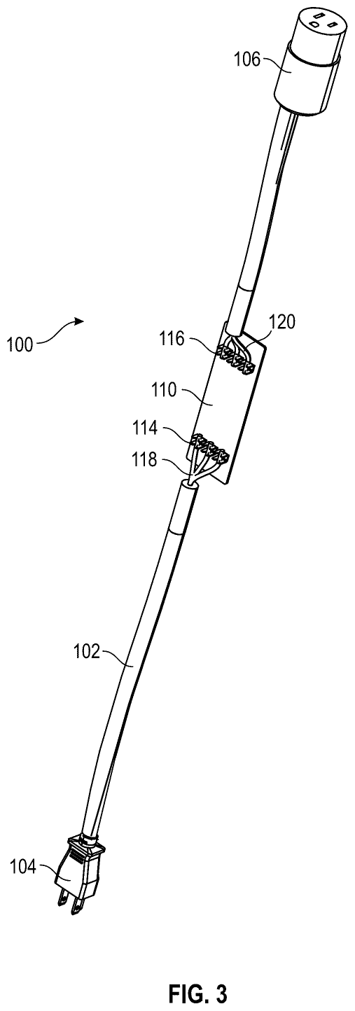

Referring to FIGS. 1-2, in some embodiments, the housing 108 may take a variety of formfactors, as shown. Further, the housing 108 may be formed as a rugged overmold to ensure Ingress Protection, structural durability, and cable pull strength. In some embodiments, the housing 108 may comprise a magnet to allow the housing to magnetically couple to a metallic surface, allowing a user to effectively mount and easily view the power indicator 100 without requiring other componentry. Referring to FIG. 3, the housing 108 has been removed to better illustrate the transformer 110 and wire connections thereto. As shown, the transformer 110 may be a printed circuit board (PCB) that comprises a first set of insulation displacement connectors 114 on a first end and a second set of insulation displacement connectors 116 on a second end. The first set of insulation displacement connectors 114 may be coupled to the male connector 104 via a plurality of first wires 118 while the second set of insulation displacement connectors 116 may be coupled to the female receptacle 106 via a plurality of second wires 120. It will be understood that each wire of the plurality of first wires 118 is coupled to a respective insulation displacement connector of the first set of insulation displacement connectors 114. Likewise, each wire of the plurality of second wires 120 is coupled to a respective insulation displacement connector of the second set of insulation displacement connectors 116. The plurality of first wires 118 electrically couple the male connector 104 to the PCB transformer 110, and the plurality of second wires 120 electrically couple the female receptacle 106 to the PCB transformer. By being interposed between the female receptacle 106 and male connector 104, the PCB transformer 110 does not require a separate power source to operate, but utilizes the power flowing through the plurality of first wires 118 and plurality of second wires 120.

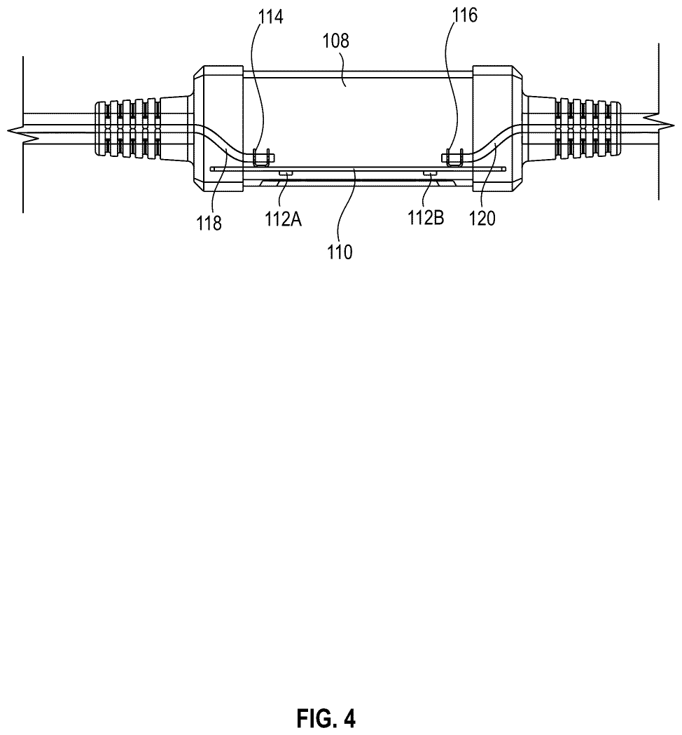

FIG. 4 illustrates a side elevation view of the power indicator 100 with the housing 108 shown transparently. As shown, the plurality of first wires 118 enter the housing 108 on a first side and are coupled to the PCB transformer 110 via the first set of insulation displacement connectors 114. The plurality of second wires 120 enter the housing 108 from a second end and are coupled to the PCB transformer 110 via the second set of insulation displacement connectors 116. As shown, one or more LEDs (light-emitting diodes) 112A-B may be used to indicate to a user when power is present and a block heater is drawing power (such as when 1-15 amps passes through the PCB transformer 110). It will be understood that the PCB transformer 110 is shown simplified for ease of understanding the configuration of the components coupled thereto, but a standard PCB transformer known in the art is contemplated. However, it will also be understood that other transformer configurations may be used, such as those not directly mounted to a PCB.

As shown in FIG. 4, the LEDs 112A-B may be housed within the housing 108. In this example, at least a portion of the housing (e.g., where the LEDs are located) is transparent or semi-transparent so as to allow a user to see when the LEDs 112A-B are illuminated. In some embodiments, the entire housing 108 is transparent or semi-transparent. By having the LEDs 112A-B within a transparent housing 108, Ingress Protection is enhanced, reducing failure and increasing longevity of the product. However, as shown in FIG. 1, in some embodiments, the LED 112 may be exposed on an exterior of the housing 108, whereby the housing 108 need not be transparent.

Still referring to FIG. 1, in some embodiments, the female receptacle 106 may comprise an LED 107 and/or the male connector 104 may comprise an LED 105 each configured to illuminate when voltage is present. Such a configuration allows a user to easily troubleshoot power connections and the block heater. For example, if the female receptacle 106 is illuminated, a user knows that the male connector 104 is properly connected to grid power (or another power source). Accordingly, if a user connects a block heater to the female receptacle 106 and the one or more LEDs 112A-B do not illuminate, a user is able to quickly determine that the fault lies with the block heater.

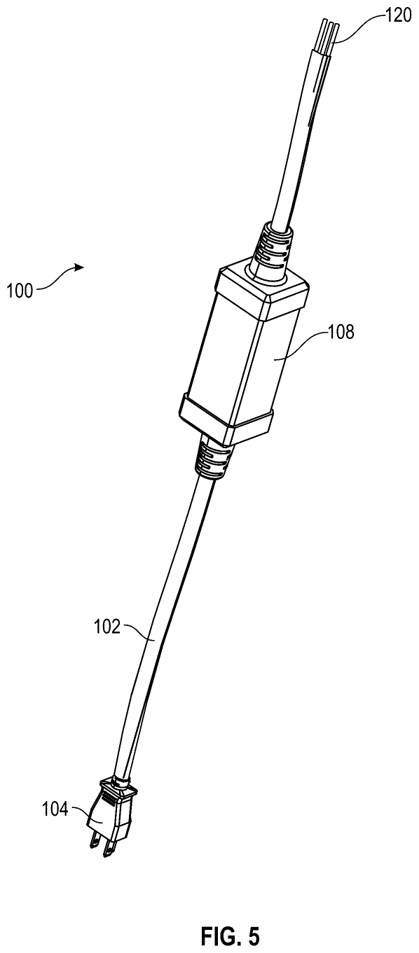

Referring to FIG. 5, in some embodiments, the power indicator 100 may be configured as a pigtail. In other words, rather than a female receptacle, the plurality of second wires 120 may remain exposed, allowing a user to splice or otherwise connect the plurality of second wires 120 to a desired device, such as a block heater.

While the embodiments above describe the use of a transformer 110, which is beneficial due to its passive nature, it will be appreciated that other apparatuses may be used that are capable of reading a load or otherwise determining that the block heater is drawing power. Without limitation, such apparatuses may include hall effect sensors, shunt resistors, surface-mounted devices (SMDs), Rogowski coils, Fluxgate sensors, magneto-resistive sensors, fiber optic current sensors, and others. It will also be appreciated that the power indicator 100 may further comprise a manual or electric switch, allowing a user to control the operation and power flow through the transformer 110. In other words, a user could leave the male connector 104 coupled to a power source and the female receptacle 106 coupled to a block heater (or other device). Rather than unplugging one end, a user may simply actuate the switch to open the current and stop the flow of power through the transformer 110. When a user desires to power the device again, they need simply actuate the switch once more.

In some embodiments, the power indicator may further comprise a microcontroller and wireless transceiver, wherein the microcontroller is configured to process voltage and current readings and transmit those readings to a user via the wireless transceiver. This may allow a user to see the power status on a handheld device such as a smartphone or tablet. Additionally, in some embodiments, a user may program the microcontroller (via a smartphone, for example) to open or close a circuit at certain triggering events. For example, a user may program the microcontroller to provide power to the engine block when an ambient temperature (such as by incorporating a temperature sensor) falls below a certain threshold, or at a scheduled time (e.g., 4 hours before estimated use of the ICE). By so doing, a user may better control their electricity costs for a block heater (as opposed to a block heater that is powered on needlessly overnight).

Accordingly, in one method of use, a user will couple the male connector 104 of the extension cord 102 to a power source (e.g., grid power), and will couple the female receptacle 106 to the male connector of the block heater, thereby closing a circuit. If the extension cord 102 is connected to power and the block heater is drawing power, placing a load on the circuit, one or more LEDs 112A-B illuminate to indicate to a user that the block heater is functioning. If the power indicator is configured as a pigtail (i.e., FIG. 5), the user may couple the plurality of second wires 120 to the desired device, such as a block heater. The user may then plug the male connector 104 into power (grid power, generator, etc.) to activate the block heater, closing the circuit. Again, if the block heater draws power and places a load on the circuit, one or more LEDs 112A-B will illuminate, allowing a user to ensure that the block heater is powered.

While the embodiments described above use a block heater for use with an ICE, it will be appreciated that other uses of the power indicator disclosed herein are contemplated. For example, a user may wish to verify that any number of devices, such as a battery charger or offsite motor or conveyor, are receiving power. Accordingly, the power indicator disclosed herein may be used with devices other than block heaters without departing herefrom.

Therefore, it will be appreciated that the power indicator 100 disclosed herein solves the need for an apparatus configured to indicate when there is a voltage load and current draw on the cable, indicating that power is flowing through an extension cord and that the block heater, or other device, is drawing that power.

It will be appreciated that systems and methods according to certain embodiments of the present disclosure may include, incorporate, or otherwise comprise properties or features (e.g., components, members, elements, parts, and/or portions) described in other embodiments. Accordingly, the various features of certain embodiments can be compatible with, combined with, included in, and/or incorporated into other embodiments of the present disclosure. Thus, disclosure of certain features relative to a specific embodiment of the present disclosure should not be construed as limiting application or inclusion of said features to the specific embodiment unless so stated. Rather, it will be appreciated that other embodiments can also include said features, members, elements, parts, and/or portions without necessarily departing from the scope of the present disclosure.

Moreover, unless a feature is described as requiring another feature in combination therewith, any feature herein may be combined with any other feature of a same or different embodiment disclosed herein. Furthermore, various well-known aspects of illustrative systems, methods, apparatus, and the like are not described herein in particular detail in order to avoid obscuring aspects of the example embodiments. Such aspects are, however, also contemplated herein.

Exemplary embodiments are described above. No element, act, or instruction used in this description should be construed as important, necessary, critical, or essential unless explicitly described as such. Although only a few of the exemplary embodiments have been described in detail herein, those skilled in the art will readily appreciate that many modifications are possible in these exemplary embodiments without materially departing from the novel teachings and advantages herein. Accordingly, all such modifications are intended to be included within the scope of this invention.

What is claimed is:

1. A power indicator, comprising:
a male connector at a first end;
a female receptacle at a second end;
a transformer interposed between the male connector and the female receptacle, the transformer electrically coupled to the male connector and female receptacle; and
a light-emitting diode (LED) electrically coupled to the transformer;
wherein the transformer is configured to read a load on a circuit and illuminate the LED when the load is above a predetermined threshold.

2. The power indicator of claim 1, wherein the transformer is enclosed within a housing.

3. The power indicator of claim 2, wherein the housing is at least partially transparent.

4. The power indicator of claim 2, wherein the LED is positioned on an external surface of the housing.

5. The power indicator of claim 1, wherein the transformer is configured as printed circuit board (PCB) transformer.

6. The power indicator of claim 5, wherein a plurality of first wires extend from the male connector and are each coupled to a respective insulation displacement connector on a first end of the PCB transformer.

7. The power indicator of claim 6, wherein a plurality of second wires extend from the female receptacle and are each coupled to a respective insulation displacement connector on a second end of the PCB transformer.

8. The power indicator of claim 1, comprising a plurality of LEDs, each configured to illuminate when the transformer detects the load on the circuit is above a predetermined threshold.

9. The power indicator of claim 8, wherein the transformer and LEDs are each positioned within a semi-transparent housing.

10. A power indicator, comprising:
a male connector at a first end, the male connector coupled to a plurality of first wires;
a plurality of second wires at a second end;
a housing comprising a printed circuit board (PCB) transformer therein, the PCB transformer interposed between the plurality of first wires and the plurality of second wires, the plurality of first wires each coupled to a respective insulation displacement connector on a first end of the PCB transformer, and the plurality of second wires each coupled to a respective insulation displacement connector on a second end of the PCB transformer;
at least one light-emitting diode (LED) within the housing and electrically coupled to the PCB transformer, wherein at least a portion of the housing proximal to the at least one light-emitting diode is semi-transparent; and
wherein the PCB transformer is configured to read a load on a circuit and illuminate the at least one LED when the load is above a predetermined threshold.

11. The power indicator of claim 10, wherein the plurality of second wires are coupled to a female receptacle.

12. The power indicator of claim 11, wherein the female receptacle comprises an LED therein, the female receptacle being at least partially semi-transparent.

13. The power indicator of claim 10, wherein the male connector comprises an LED therein, the male connector being at least partially semi-transparent.

14. A method of indicating a load on a circuit using a power indicator, the method comprising:
plugging a male connector into a power source;
coupling a female receptacle to a device requiring power, thereby closing a circuit;
wherein at least one light-emitting diode (LED) is configured to illuminate when a transformer interposed between the male connector and the female receptacle detects the load on the circuit that is above a predetermined threshold.

15. The method of claim 14, wherein the male connector illuminates when coupled to the power source.

16. The method of claim 14, wherein the transformer is positioned within a transparent housing and wherein the at least one LED is positioned within the transparent housing to illuminate the transparent housing when the load is detected.

17. The method of claim 14, wherein the device requiring power is an engine block heater.

18. The method of claim 14, wherein the predetermined threshold for the load on the circuit is in a range between 1 and 15 amps.
